(19) United States
(12) Patent Application Publication
(10) Pub. No.: US 2011/0272024 A1
(43) Pub. Date: Nov. 10, 2011

(54) MULTI-LAYER SiN FOR FUNCTIONAL AND OPTICAL GRADED ARC LAYERS ON CRYSTALLINE SOLAR CELLS

(75) Inventors: Dongwon Choi, San Jose, CA (US); Michael P. Stewart, San Francisco, CA (US); Li Xu, Tai Chung City (TW); Hemant P. Mungekar, Campbell, CA (US); Sunhom Paak, Saratoga, CA (US); Kenneth MacWilliams, Los Altos Hills, CA (US)

(73) Assignee: APPLIED MATERIALS, INC., Santa Clara, CA (US)

(21) Appl. No.: 13/076,295

(22) Filed: Mar. 30, 2011

Related U.S. Application Data
(60) Provisional application No. 61/323,755, filed on Apr. 13, 2010.

(51) Int. Cl. H01L 31/0232; H01L 31/18; C23C 16/34; C23C 16/50; C23C 16/52; H01L 31/0216; H01L 21/66

(52) U.S. Cl. 136/259; 136/256; 438/72; 438/17; 118/723 R; 257/E31.119; 257/E21.531

(57) ABSTRACT

Embodiments of the invention include a solar cell and methods of forming a solar cell. Specifically, the methods may be used to form a passivation/anti-reflection layer having combined functional and optical gradient properties on a solar cell substrate. The methods may include flowing a first process gas mixture into a process volume within a processing chamber generating plasma in the processing chamber at a power density of greater than 0.65 W/cm² depositing a silicon nitride-containing interface sub-layer on a solar cell substrate in the process volume, flowing a second process gas mixture into the process volume, and depositing a silicon nitride-containing bulk sub-layer on the silicon nitride-containing interface sub-layer.

### CROSS-REFERENCE TO RELATED APPLICATIONS

This application claims benefit of U.S. Provisional Patent Application Ser. No. 61/323,755 (APPM/014742L), filed Apr. 13, 1010, which is herein incorporated by reference.

### BACKGROUND OF THE INVENTION

1. Field of the Invention

Embodiments of the present invention generally relate to the fabrication of solar cells and particularly to the passivation of silicon solar cells.

2. Description of the Related Art

Solar cells are photovoltaic devices that convert sunlight directly into electrical power. The most common solar cell material is silicon (Si), which is in the form of single, polycrystalline, multi-crystalline substrates, or amorphous films. Efforts to reduce the cost of manufacturing solar cells, and thus the cost of the resulting cell, while maintaining or increasing the overall efficiency of the solar cell produced are ongoing.

The efficiency of a solar cell may be enhanced by use of a passivation layer that also functions as an anti-reflective coating (ARC) over an emitter region in a silicon substrate that forms the solar cell. When light passes from one medium to another, for example from air to glass, or from glass to silicon, some of the light may reflect off of the interface between the two media. The fraction of light reflected is a function of the difference in refractive index between the two media, wherein a greater difference in refractive indices of two adjacent media results in a higher fraction of light being reflected from the interface therebetween.

The efficiency at which a solar cell converts incident light energy into electrical energy is adversely affected by a number of factors, including the fraction of incident light that is reflected off of a solar cell and absorbed in the cell structure, such as a passivation layer, and the recombination rate of electrons and holes in solar cell. Each time an electron-hole pair recombines, charge carriers are eliminated, thereby reducing the efficiency of the solar cell. Recombination may occur in the bulk silicon of a substrate, which is a function of the number of defects in the bulk silicon, or on the surface of a substrate, which is a function of how many dangling bonds, i.e., unterminated chemical bonds, are present.

Thorough passivation of a solar cell by using a passivation layer greatly improves the efficiency of the solar cell by reducing recombination rates, yet, the refractive index (n) needs to be tuned with the surrounding layers to minimize light reflection while also maintaining desired light absorption capabilities of the solar cell. Typically, a thin transparent film has an inherent extinction coefficient (k), the magnitude of which is an indication of the amount of light absorbed by the film, and an index of refraction (n), the magnitude of which is indicative of the degree to which the light bends when passing from one medium into another.

In films such as SiN which are useful for passivation, the magnitude of the n and k values is linked, in that if one is high, the other is likewise high. Because the range of the index of refraction of the passivation film is limited by the materials within which it is sandwiched, the range of resulting k values is also thus limited within the practice of the prior art, and thus an unacceptably high k value is seen as an unavoidable consequence of an acceptable index of refraction.

Additionally, the deposition rate, and thus the ultimate number of substrates which can receive a desired film layer in a set period of time, has an effect on the index of refraction and k values, as well as the physical properties of the film, such as the size or length of grains and grain boundaries in the film. Large grains, and resulting long grain boundaries, lead to pathways for contaminate ingress through the passivating film to the silicon, leading to failure of the cell. Thus, higher deposition rates used to produce a greater number of solar cells per unit time, which are enabled for plasma deposition processes, result in larger grains and thus pinholes.

Therefore, there is a need for an improved method of forming a passivation layer that has combined functional and optical gradient properties which minimize surface recombination of the charge carriers, improve the formed solar cell efficiency, and result in a substantially pinhole free passivation layer that has desirable optical and passivating properties.

### SUMMARY OF THE INVENTION

In light of the above, embodiments of the present invention generally provide methods for a coating that may act as both a high-quality passivation and ARC layer for solar cells. The method, according to one embodiment, includes forming a multi-layer passivation and ARC coating by flowing a first process gas mixture into a process volume within a processing chamber, generating plasma in the processing chamber at a power density of greater than 0.65 W/cm², depositing a silicon nitride-containing interface sub-layer on a solar cell substrate in the process volume, flowing a second process gas mixture into the process volume, and depositing a silicon nitride-containing bulk sub-layer on the silicon nitride-containing interface sub-layer.

In another embodiment, a method for detecting pin-holes formed in a passivation layer on a solar cell is disclosed. The method includes immersing a solar cell having a silicon-nitride containing passivation layer formed thereon in a copper electrolyte, applying current through the metal covered rear-side of the solar cell to plate any pinholes that extend from an outer surface of the passivation layer to a doped region of the solar cell, and detecting any outgrown copper that plates in any pinholes.

In yet another embodiment, a solar cell is disclosed that includes a substrate having a junction region and a passivation anti-reflection layer on a surface of the substrate. The passivation anti-reflection layer includes a silicon nitride-containing interface sub-layer and a silicon nitride-containing bulk sub-layer directly on the interface sub-layer, wherein the interface sub-layer has a refractive index (n) greater than the bulk sub-layer and wherein the passivation layer is substantially free of pinholes that entirely pass though both the interface sub-layer and the bulk sub-layer.

In another embodiment, a system for forming a film on a solar cell is disclosed. The system includes a plasma processing chamber for forming a passivation/ARC layer on a solar cell substrate within a processing volume of the processing chamber, the passivation/ARC layer comprising a silicon nitride-containing interface sub-layer formed on the solar cell substrate using plasma generated from a first process gas mixture at a power density of greater than 0.65 W/cm² and a silicon nitride-containing bulk sub-layer formed on the interface sub-layer using plasma generated from a second process gas mixture at a power density of greater than 0.65 W/cm². The system also includes a system controller in communication with the plasma processing chamber, the system controller configured to control the plasma power density, the first process gas mixture flow rates, and the second process gas mixture flow rates so that the interface sub-layer has a refractive index (n) greater than that of the resulting bulk sub-layer and both the interface sub-layer and the bulk sub-layer have an extinction coefficient (k value) from 0 to 0.1.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1F depict cross-sectional views of a portion of a substrate corresponding to various stages of the process illustrated in FIG. 2.

FIG. 2 depicts a process flow diagram of a passivation layer formation process performed on a solar cell substrate in accordance with one embodiment of the invention.

FIG. 3 is a schematic side view of a parallel plate PECVD system that may be used to perform embodiments of the invention.

FIG. 4 is a top schematic view of one embodiment of a process system having a plurality of process chambers.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally provides methods of forming a high quality passivation layer to form a high efficiency solar cell device. Solar cell substrates that may benefit from the invention include substrates that have an active region that contains single crystal silicon, multi-crystalline silicon, polycrystalline silicon, and amorphous silicon i.e. thin film cells, but may also be useful for substrates comprising germanium (Ge), gallium arsenide (GaAs), cadmium telluride (CdTe), cadmium sulfide (CdS), copper indium gallium selenide (CIGS), copper indium selenide (CulnSe₂), gallium indium phosphide (GalnP₂), organic materials, as well as heterojunction cells, such as GalnP/GaAs/Ge or ZnSe/GaAs/Ge substrates, that are used to convert sunlight to electrical power.

In general, a passivation layer will have desirable optical properties to minimize light reflection and absorption as light passes through the passivation layer, and desirable functional properties to “surface” passivate the surface(s) it is disposed over, “bulk” passivate the adjacent regions and surface of the substrate, and store positive charge in the passivation layer or “field” passivate. Thus, a passivation layer contains a desirable concentration of hydrogen to heal shallow defects found at the substrate surface. The mechanism by which the passivation layer is able to perform these functions includes, for example, the ability of a formed passivation layer to be a source of hydrogen (H⁺) that is used to correct defects in regions of the substrate, and the physical and/or chemical characteristics of the formed layer that are able to tie-up the dangling bonds at the substrate surface.

Balancing the desired properties of a passivation layer for a solar cell is challenging, especially when the passivation layer also functions as an antireflective coating. The challenge increases when using silicon nitride (SiₓN_{y}, also abbreviated SiN) films as the passivation layer because achieving desired film properties requires balancing competing process parameters for forming a passivation layer having particular optical or functional qualities. For example, when seeking to improve the optical gradient properties of the passivation layer, it often comes at the expense of the functional properties, such as surface, bulk, and field passivation of a substrate.

Sometimes, it is even difficult to balance the properties within one area. For example, the solar cell industry has attempted to implement the optical gradient properties of a passivation layer in the past, but failed because it is difficult to obtain low extinction coefficient (k) properties in the film along with a high refractive index (n) in a typical process. Generating a film having a high index of refraction (n) also means generating a film having a high extinction coefficient (k) when using typical film formation methods. In other words, the variables n and k mirror each other where n and k generally go up or down together when forming a film according to conventional methods. Independence between the magnitude of k and n values would provide the ability to combine the desired optical and functional properties into a passivation layer, i.e. to enable a lower k, and thus less light loss, and at the same time a higher n, and thus lower reflectance. It should be noted that the measured values of n and k are dependent on frequency i.e. the wave length of light, at which they are measured. The k and n values discussed herein are measured at 400 nm and 633 nm respectively.

Surface recombination velocity (SRV) of a film is another difficult property of the passivation anti-reflective layer that needs to be balanced with all the other properties. SRV is the rate at which free electrons and holes at the surface of a substrate recombine, thus neutralizing each other. Additionally, in order to achieve desired film properties in one area, such as desired functional properties as opposed to desired optical properties, reduced film deposition rates may be required and thus decreasing throughput and production.

Thus, it is generally hard to form a silicon nitride (SiₓN_{y}) passivation layer that combines the functional and optical properties without compromises that result in properties which are individually suboptimal, because the SiN material cannot provide these properties independently of one another.

Embodiments of the invention generally provide a method of forming a passivation/anti-reflection layer that provides the ability to combine desired functional properties and desired optical gradient properties, wherein the source of the linkages of the properties found in the prior art is avoided. The inventors have discovered that by using a higher power for depositing silicon nitride, k and n tend to be more independent than when using normal power ranges, which typically are between 2,000-3,000 Watts (W). High plasma power density permits formation of desired film properties exhibiting both optical and functional gradient properties that are not a compromise based on traditional couplings of high k values to high n values and low k values with low n values, and yet, by using a multi-layer deposition for forming the passivating layer, pinholes extending through the entire film layer are avoided.

Thus, embodiments of the present invention provide a method of forming a passivation/ARC layer with a high refractive index but with a low extinction coefficient (k). By specific tailoring of the process chemistries for film formation, each sub-layer in the multilayer passivation film may have specific properties that together combine and form a passivation/ARC layer having desired optical and functional properties.

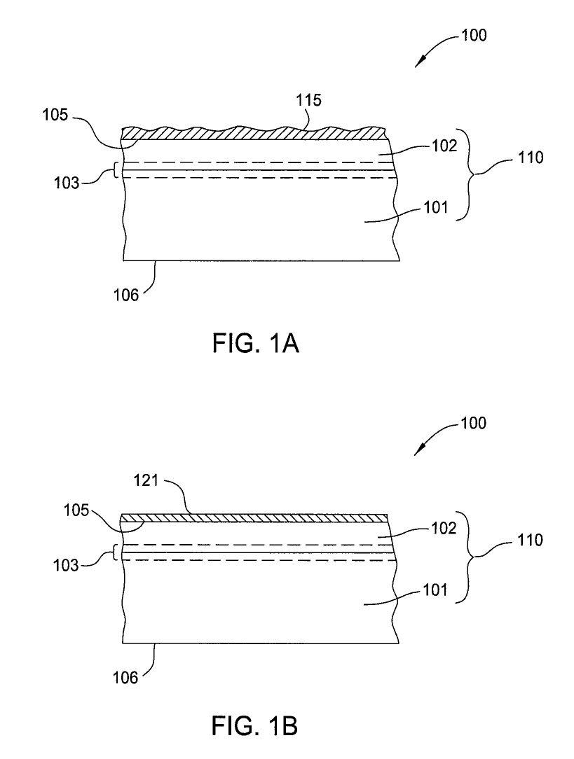

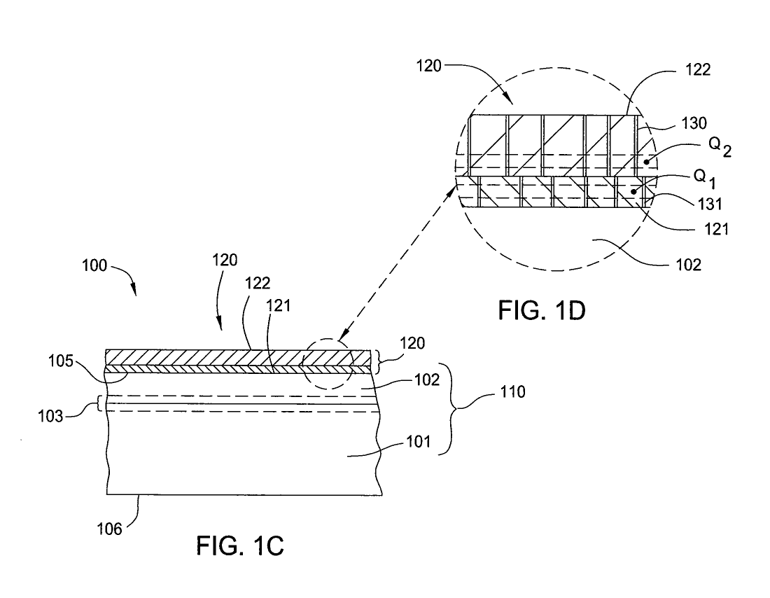

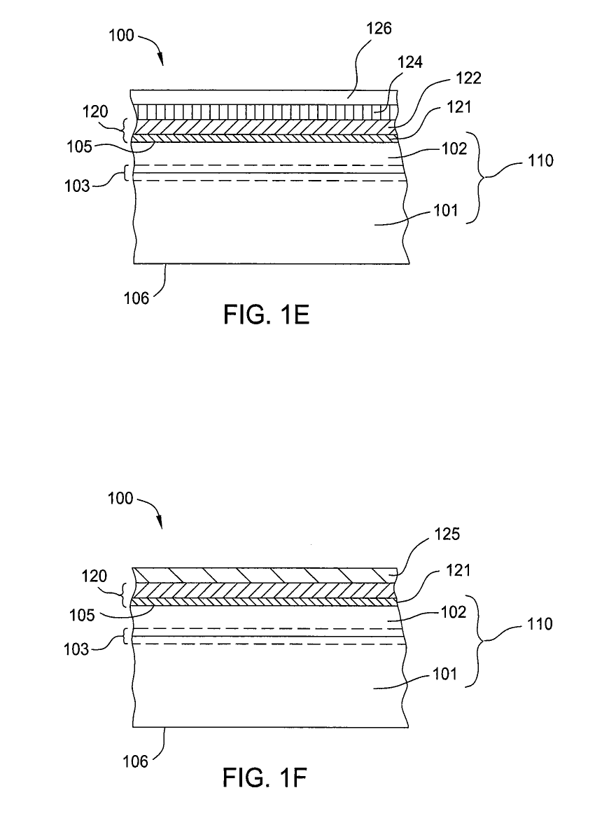

In one embodiment, the passivation layer may comprise one or more layers, or graded regions, that have a differing composition, differing physical properties, and/or differing electrical properties to provide a passivating effect and optical properties. For example in one embodiment, a passivation layer 120 comprises a silicon nitrogen-containing interface sub-layer 121 and a silicon nitrogen-containing bulk sub-layer 122 formed on the interface sub-layer 121, as shown in FIGS. 1C-1F.

### Passivation Layer Formation Process

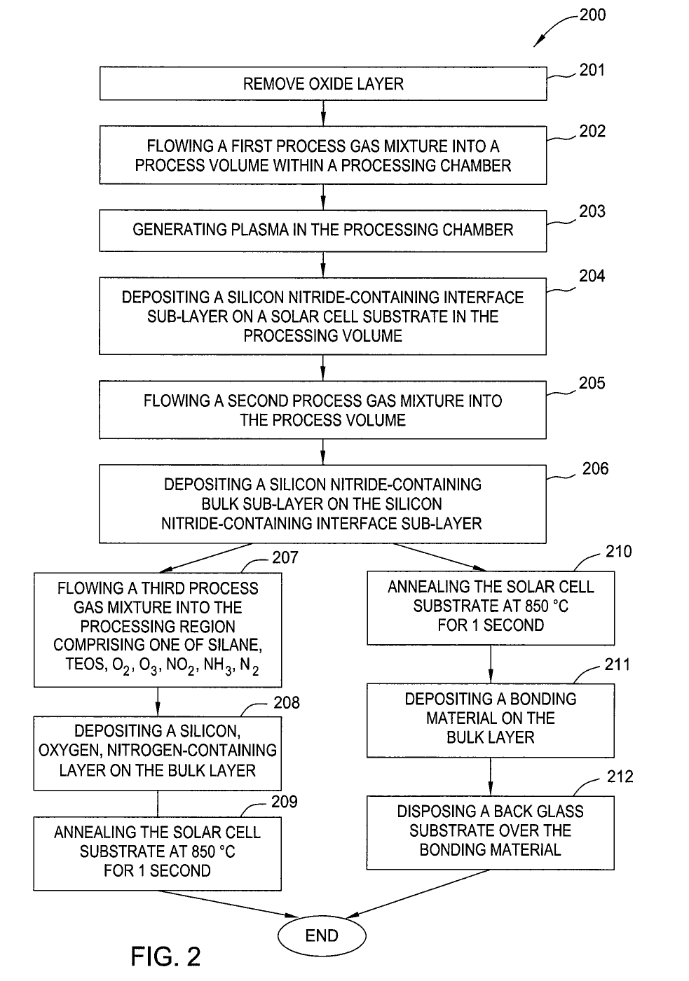

FIGS. 1A-1F illustrate schematic cross-sectional views of a solar cell substrate 110 during different stages in a processing sequence used to form a passivation/ARC layer 120 on a surface (e.g., top surface 105) of a solar cell 100. FIG. 2 illustrates a process sequence 200 used to form the passivation layer on a solar cell substrate 110. The sequences found in FIG. 2 correspond to the stages depicted in FIGS. 1A-1F. In one embodiment of the solar cell 100, a p-type substrate 110, having a bottom surface 106 and comprising crystalline silicon, has a base region 101 and an n-doped emitter region 102 formed thereon, typically by a doping and diffusion/anneal process, although other processes including ion implant may be used. The substrate 110 also includes a p-n junction region 103 that is disposed between base region 101 and emitter region 102 of the solar cell, and is the region in which electron-hole pairs are generated when solar cell 100 is illuminated by incident photons of light.

While the discussion below primarily discusses a method and apparatus for processing a substrate having an n-type emitter region formed over a p-type base region, this configuration is not intended to limit the scope of the inventions described herein, since the passivation layer could also be formed over an n-type base region, p-type emitter solar cell configuration.

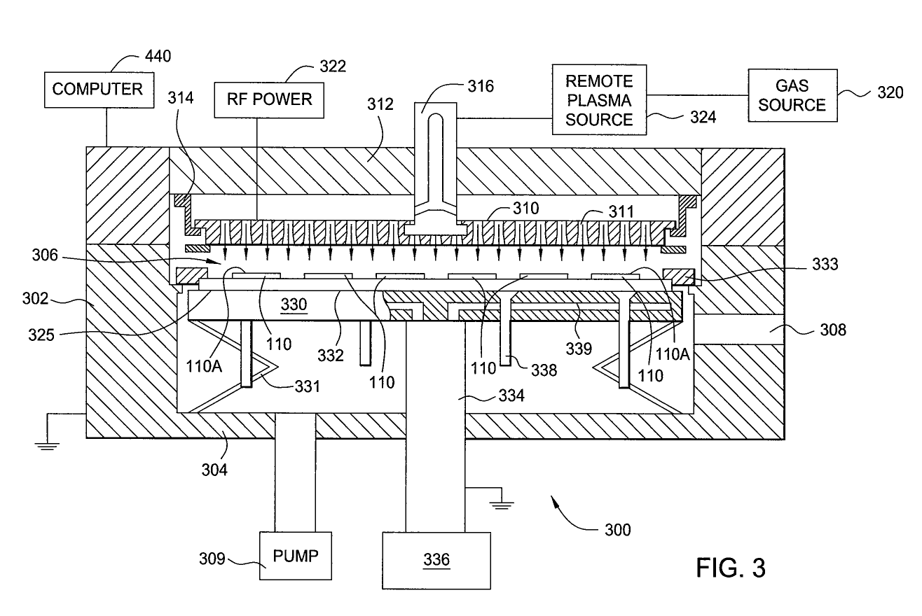

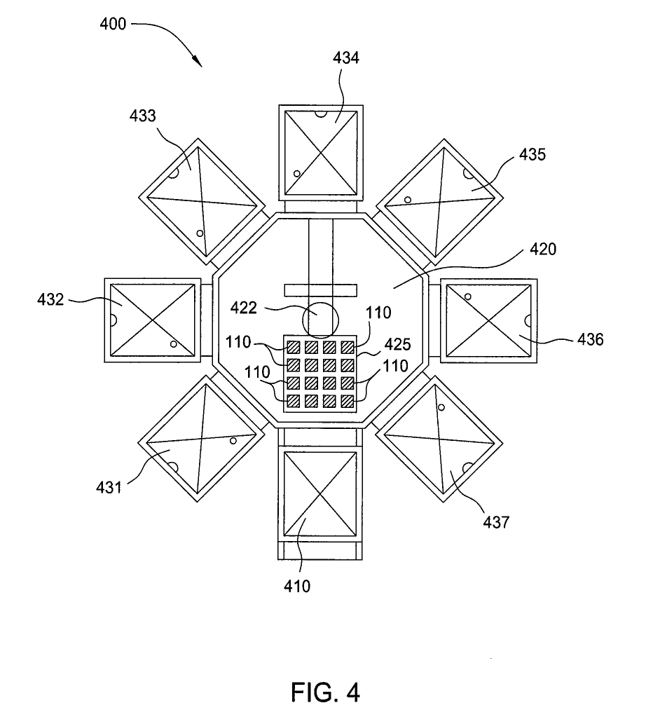

Referring to FIG. 2, during the process sequence 200 the surfaces of the substrate 110 are subjected to a plurality of processes that are used to form the interface sub-layer 121 and bulk sub-layer 122 on the surfaces of the substrate. The following are examples of processes 201-205 that may be performed in a processing chamber similar to processing chamber 300 (FIG. 3). In one embodiment, all of the processes performed in the process sequence 200 are performed in one or more of the processing chambers 431-437 (FIG. 4) found in one or more systems 400.

The process sequence 200 used to form the passivation layer on a solar cell substrate 110 generally begins by removing native oxide from the underlying substrate, as shown at process 201 in FIG. 2. During normal processing of a solar cell device, a native oxide layer 115 will form on one or more of the surfaces of the substrate 110. At process 201, the surfaces of the substrate 110 are cleaned to remove the oxide layer 115 (FIG. 1A). In one embodiment, the clean process 201 may be performed using a dry cleaning process in which the substrate 110 is exposed to a reactive plasma etching process to remove the oxide layer 115. In one embodiment, at process 201, after disposing one or more of the substrates 110 in a processing chamber, such as chamber 300 in FIG. 3, the native oxide layer 115 is exposed to a reactive gas, which may comprise nitrogen, fluorine, and hydrogen. Next, the oxide layer 115 that reacted with the reactive gas(es) is thermally treated to remove it from the surface of the substrate. In some embodiments, the thermal treatment may be an annealing process performed in the processing chamber 300, or another adjacent chamber found in the system 400.

In some cases, it may be desirable to assure that the substrate is not exposed to oxygen for extended periods of time. Therefore, in some embodiments of the invention, it is desirable to perform each of the processes 203-208 in an oxygen-free inert and/or vacuum environment, such as in the vacuum process volumes of a cluster tool, or system 400 (FIG. 4), so that the substrate is not exposed to oxygen between the processes 203-208.

In one embodiment, after performing process 201 on a batch of substrates 110 that are disposed on a substrate carrier 425, the substrates are then positioned in a processing chamber so that the processes performed at 202-206 can be performed on the substrates. Next, as shown in FIGS. 1B and 2, a silicon nitride-containing interface sub-layer 121 is formed on the cleaned, oxide removed, surface 105 of the substrate. In one embodiment, the interface sub-layer 121 may be between about 50 Angstroms (Å) and about 350 Å thick, such as 150 Å thick. In one embodiment, the interface sub-layer 121 is formed over the top surface 105 using a chemical vapor deposition (CVD), plasma enhanced chemical vapor deposition (PECVD), or a physical vapor deposition (PVD) technique.

At process 202, in one aspect the method of forming the interface sub-layer 121 includes flowing a first process gas mixture in a process volume 306 within a processing chamber. At process 203, a plasma is generated in the process volume 306 and at 204 a silicon nitride-containing interface sub-layer 121 is deposited on a solar cell substrate 110 in the process volume 306 at process 204.

Next, at process 205 as shown in FIGS. 1C-1D and 2, a silicon nitrogen-containing bulk sub-layer 122 is formed on the interface sub-layer 121 using a plasma enhanced chemical vapor deposition (PECVD) process, thereby forming a multilayer passivation anti-reflection coating 120. Alternatively, the bulk sub-layer 122 may be formed over the interface sub-layer 121 using a chemical vapor deposition (CVD) or a physical vapor deposition (PVD) technique. PVD processes may be used for reactive sputtering within an atmosphere of hydrogen to form a multilayer passivation anti-reflection layer. For example, a silicon target could be sputtered with argon in a nitrogen and hydrogen atmosphere to deposit various SiN layers. In one embodiment, the bulk sub-layer 122 may be between about 400 Å and about 700 Å thick, such as 600 Å thick. In one example, the substrate is exposed to a 13.56 MHz RF plasma to form both interface sub-layer 121 and bulk sub-layer 122.

In one embodiment the first and second process gas mixtures comprise a silicon containing precursor and a nitrogen containing precursor. For example, the first process gas mixture may comprise silane (SiH₄), nitrogen (N₂), and/or ammonia (NH₃). The second process gas mixture may comprise silane and nitrogen, silane and ammonia (NH₃), or silane, ammonia, and nitrogen. Table 1 details an example of the process conditions that may be used for forming the interface sub-layer 121 and the bulk sub-layer 122 by PECVD. Table 1 lists the flow rates of SiH₄, nitrogen, and/or ammonia, on a per liter of process volume basis. Table 1 also includes the ratio of the nitrogen-containing precursor (e.g., N₂) to the flow rate of the silicon-containing precursor (e.g., SiH₄), the power density of each deposition process, the spacing between the showerhead and the substrate support, and the deposition time for each sub-layer. For example, in one embodiment for forming the interface sub-layer 121, the nitrogen flow rate is about 77.30 standard cubic centimeters (sccm) per liter of process volume and the silane flow rate is about 5.25 sccm per liter of process volume. The interface sub-layer 121 may be deposited at a rate from 1,000 ↑ to 3,000 Å per minute, for example 1,100 Å per minute while the bulk sub-layer 122 may be deposited at a rate greater than 3,000 Å per minute.

In another embodiment, the second process gas mixture may also include a hydrogen gas (H₂) diluent that may be added at a flow rate of 110 sccm per liter of chamber volume to the silane, ammonia, and nitrogen flow rates shown in Table 1. Though not shown in Table 1, the ammonia to silane flow rate ratio may be about 0.90 in the bulk sub-layer process recipe. It is believed that carefully control of silane gas flow helps to achieve the desired film optical and functional properties. In the bulk sub-layer process conditions, the process gas flows are generally higher. A person of ordinary skill could successfully modify the gas flow ratios depending on the power, pressure, spacing, and temperature of the deposition process.

TABLE 1

| | | NH₃ | SiH₄ | | Power | | |
|---|---|---|---|---|---|---|---|
| | N₂ flow | flow | flow | N₂/ | Density | | |
| | rate | rate | rate | SiH₄ | (W/ | Spacing | Time |
| | (sccm/l) | (sccm/l) | (sccm/l) | ratio | cm²) | (mils) | (Sec.) |
| Interface | 77.30 | 0.00 | 5.25 | 14.70 | .65-1.0 | 800 | 9 |
| sub-layer | | | | | | | |
| Bulk | 77.30 | 8.40 | 9.20 | 8.35 | .65-1.0 | 1100 | 15 |
| sub-layer | | | | | | | |

In one embodiment, the temperature of a substrate for both the interface and bulk sub-layer deposition processes may be maintained from 350° C. to 400° C., such as from 380° C. to 390° C. Various means for maintaining the substrate temperature may be load lock heating, substrate support heating, plasma heating, etc. Both sub-layers may deposited at a chamber pressure of about 1.5 Torr.

The plasma for each sub-layer may be provided by RF power between about 4,350 W and about 6,700 W, such as about 5,000 W at a frequency of 13.56 MHz compared to the 2,000-3,000 W range of typical SiN deposition processes. The RF power may be provided to the showerhead 310 and/or a substrate support 330. The RF power density for both the interface sub-layer and bulk sub-layer deposition may be about 0.65 W/cm² of substrate surface or greater to generate the plasma. For example, the RF power density may be 1.00 W/cm² in some embodiments. In another embodiment, the RF power density may about 0.75 W/cm². The power density may be as high as possible, as higher power provides increased positive charge in the interface and bulk sub-layers. Thus, a higher power provides better field passivation and lowers SRV.

In another embodiment, the demarcation between the interface and bulk sub-layers can be more clearly defined with an abrupt transition by stopping and restarting the plasma while the process gases transition from the interface sub-layer recipe to the bulk sub-layer recipe. This transition may occur in various ways. For example, the flow of the first process gas mixture may be stopped before the second process gas mixture is introduced into the processing chamber. In another example, only the silane gas flow is stopped while the remaining precursor(s) of the first process gas mixture continue to flow. For example, the gas flow recipe for the interface sub-layer can transition to the bulk sub-layer recipe during the period when the power is off. The gas flows will not provide perfect gas mixing instantly. Thus, this break in the plasma deposition process will allow the gases for the bulk passivation layer recipe to properly mix before restarting the plasma power. The process “break” performed after process 204 may last about 2 seconds, which permits substantial purging of the first process gas mixture from the chamber before the second process gas mixture is flowed into the chamber.

During the transition between process recipes, the silane flow may be ramped up to distribute it equally through the chamber, followed by resupplying the power to the showerhead to reignite the plasma, and thereby finish forming the passivation layer 120. Turning off the plasma power after interface sub-layer deposition and restarting the plasma for bulk sub-layer deposition increases the density of the film and the final efficiency by making a more ideal and abrupt transition layer. During the break, the substrate temperature is generally maintained at a temperature of about 380° C. to 390° C. In other embodiments, the power could be ramped up to its final power settings during the bulk sub-layer deposition process. In some tests, stopping and restarting the power may increase the open circuit voltage (V_{OC}) of the film by 3 millivolts.

In another embodiment, the formation of the bulk sub-layer may occur by transitioning flows from the interface sub-layer recipe to the bulk sub-layer recipe, such as those shown in Table 1, without a “break”, thereby creating a transition layer of undefined stoichiometry. The gas flow rates and/or the gas mixture composition are changed to transition from one process recipe to the next process recipe while the plasma power is on. The transition layer in such an embodiment may be 3-5 nm thick or less than 10% of the bulk sub-layer thickness, but 7-8% of the total deposited passivation layer thickness.

The resulting interface sub-layer 121 and bulk sub-layer 122, as schematically illustrated in FIGS. 1C-1D, form a passivation/ARC layer 120 over a top surface 105 of a p-type doped region. In one embodiment, it is desirable to form a multilayer passivation ARC layer 120 that contains a desirable amount of trapped positive charge to provide a desirable surface passivation of the p-type region. In another embodiment, the trapped positive charge provides desirable surface passivation of an n-type substrate having an n-type doped region. In one embodiment, the sum of the total amount of the trapped positive charge Q₁ and total amount of the trapped negative charge Q₂ found in the multilayer passivation coating 120 has enough trapped charge to achieve a charge density about 1×10¹² Coulombs/cm² or greater, such as between about 1×10¹² Coulombs/cm² and about 1×10¹⁴ Coulombs/cm², or between about 2×10¹² Coulombs/cm² and 4×10¹³ Coulombs/cm². In another embodiment, the total trapped positive charge may be from about 5×10¹¹ Coulombs/cm² to about 1×10¹³ Coulombs/cm².

The lack of a negative sign in front of the desired charge density number is only intended to signify that the charge experienced by the surface 105 is positive versus negative, and thus the absolute value of Q₁ is greater than the absolute value of Q₂. In cases where the interface sub-layer 121 and the bulk sub-layer 122 each contain positive and negative charges, the values of Q₁ and Q₂ discussed herein are the net values of charge, or the sum of the absolute value of the total amount of positive charge minus the absolute value of the total amount of negative charge taken in each respective layer. Generally, the higher the amount of positive charge, the greater the lifetime of the solar cell and the lower the SRV. In some embodiments, it is desirable to position the bulk of the trapped positive charge Q₁ at 100 angstroms (Å) or less from the surface 105 to assure that the trapped charge will have a desirable field strength to repel the holes at or below the surface 105, since the ability to repel the holes will vary with the one over the square of the distance (1/d²) between trapped positive charge Q₁ and the hole(s).

Tables 2 and 3 detail various physical and electrical properties of the interface sub-layer 121 and bulk sub-layer 122 formed according to embodiments of the invention. Table 2 shows the atomic hydrogen percentage in each sub-layer, the range of refractive indices (n) and extinction coefficient (k) values, and film density. The interface sub-layer 121 may have a hydrogen (H⁺) concentration to aid in the bulk and surface passivation of a substrate 110, such as around 12 atomic %. The bulk sub-layer 122 may have a H⁺ concentration such as around 18 atomic %. During a firing or annealing process performed on the substrate after deposition of the passivation/ARC layer 120, the hydrogen in the bulk sub-layer 122 will be driven into the substrate to also provide bulk passivation of the substrate. The reservoir of H⁺ ions in the interface and bulk sub-layers can be driven to the substrate and top surface of the silicon substrate for passivating any vacancies or crystalline defects in the substrate structure. As the interface sub-layer 121 is the only layer on the top surface 105 of the substrate 110, it may have a surface recombination velocity (SRV) of less than 10 cm/sec whereas the bulk sub-layer does not come in contact with the top surface 105 and thus the SRV of the bulk sub-layer is not as important.

TABLE 2

| Film property | H % | n | k | Density (g/cm³) |
|---|---|---|---|---|
| Interface sub-layer | 5%-15% | 2.4-2.6 | <0.04 | 2.5-3.0 |
| Bulk sub-layer | 10%-25% | 2.05-2.15 | ≈0 | 2.3-2.9 |

The deposited interface sub-layer 121 may have a refractive index (n) greater than the bulk sub-layer 122 and both the interface sub-layer 121 and the bulk sub-layer 122 may have a k value from 0 to 0.1. Generally, the refractive index is selected for packaging with the resulting cell with the passivation/ARC layer 120 in contact with a bonding material that is used to encapsulate the solar cell when finishing the formation process. Some examples of appropriate bonding materials include ethyl vinyl acetate (EVA) or poly vinyl butyral (PVB). Thus, as light passes through the glass (n=1.5), the bonding material (n=1.5), the passivation/ARC layer 120 including the bulk sub-layer 122 and the interface sub-layer 121, and a silicon substrate (n=3.0), the amount of light reflected from each layer interface when passing through each medium will be decreased as the difference in refractive index between each successive media is generally small, thereby decreasing the amount of light reflected off the films below the glass yet above the emitter region 102. For example, the n values of the interface sub-layer 121 and the bulk sub-layer 122 may be 2.4 and 2.08 respectively.

Table 3 shows the range of N—H/Si—H ratios of each sub-layer, the film stress, the flat band voltage (V_{FB}) as measured at 400 Å of the film, and film thickness. The measured thickness of these various layers are thicknesses as measured on a textured surface. Thus, these thicknesses are from surface to surface of each layer. For example, if a polished substrate was used to monitor a process at the same time as the production substrates, the resulting thickness of the film layers 121, 122 on the production substrates would be less than the polished substrate by a known factor, sometimes referred to as a space factor. The space factor may be around 70% to 90%, i.e. the thickness of a layer on a production substrate may be around 70% to 90% of the thickness of the layer on the polished substrate. In one embodiment, the interface sub-layer 121 and bulk sub-layer 122 may be 150 Å and 600 Å thick respectively. Additionally, the stress in the interface and bulk sub-layers may be compressive or tensile.

TABLE 3

| | N—H/Si—H | Stress | V_{FB} | Thickness |
|---|---|---|---|---|
| Film property | ratio | (GPa) | (Volts) | (Å) |
| Interface sub-layer | 0.1-0.8 | −1.6-1.0 | ≦−8 | 50-350 |
| Bulk sub-layer | 0.5-2.0 | −0.2 | 12 | 400-700 |

The N—H/Si—H bond ratio may be important to tailor the optical properties of the sub-layers 121, 122. By increasing the power of the plasma during the deposition of passivation layer 120, it is believed that the resulting deposited film will have an increased refractive index and lowered k value compared to a passivation layer deposited at the lower plasma power settings used in the prior art, e.g. between 2,000-3,000 W. At least two types of bonds found in a silicon solar cell having a silicon-nitride type passivation layer cause absorption of light: Si—H bonds and Si—Si bonds. Si—H and Si—Si bonds, however, are not a part of a silicon nitride material, which is theoretically all Si₃N₄, sometimes referred to as stoichiometric silicon nitride. However, a stoichiometric silicon nitride film of only Si₃N₄ would be a poor solar ARC material because there would be no hydrogen therein, which would result in poor overall solar cell efficiencies as the refractive index of stoichiometric silicon nitride is around 1.9. Thus, hydrogen needs to be added to a silicon nitride ARC layer to further enhance its antireflective and passivating properties.

However, when hydrogen is added to a silicon nitride film on a silicon substrate, some of the hydrogen goes to form N—H bonds and Si—H bonds. Si—H material absorbs light at the edge of the UV range and contributes a minor portion to the total k values whereas the Si—Si material absorbs visible light and thus contributes the major portion to the total k value. Extra silicon is needed in order to get the refractive index to the desired levels for the solar cell. The extra silicon, however, does not have to be bonded to other silicon. It is believed that using a high plasma power during the deposition of the passivation layer(s) inhibits the formation of Si—Si bonds (though not necessarily completely prevents) and enhances the formation of Si—N and/or Si—H bonds in the growing film. In other words, a high plasma power density minimizes bonding of Si atoms in the growing film, and/or initially at the substrate surface, from bonding with Si atoms found in the silicon-containing precursor gas. By minimizing the Si—Si bonding and increasing the percentage of Si—N and Si—H bonds in the growing film, the k value of the deposited silicon nitride film can be adjusted and/or controlled. In some configurations, it is desirable to adjust the plasma power density to tailor and or adjust the k value of the formed silicon nitride layer. The power levels may be double the prior normal levels for forming a silicon nitride layer, in order to break the desired bonds and decouple the usually directly proportional relationship between n and k.

Thus, the interface sub-layer 121, which is in contact with a silicon substrate, has a high refractive index and optimal light transmission qualities compared to SiN passivation films formed using prior art methods, and passivates the defects at the Si—SiN interface. The bulk sub-layer 122 deposited on top of the interface sub-layer 121 may be tailored for charge storage, hydrogen retention, optimal stress, and high deposition rate compared to the interface sub-layer 121. The thicknesses of the constituent layers may be chosen to reduce absorptive loss of light, while also keeping the amount of reflected light from the layers above the emitter region to a minimum.

FIG. 1D is a close up cross-sectional view of the passivation/ARC layer 120. Pinholes 130, 131, in bulk sub-layer 122 and interface sub-layer 121 respectively, are illustrated. The pinholes depicted have a straight sidewall, though there commonly are irregular, non-linear shapes of pinholes. Chemical vapor deposition processes initiate film growth by nucleation, which is subsequently followed by grain growth. When neighboring grains keep growing up to the point of grain coalescence to form continuous films, the entire substrate area is covered with the film. However, due to the nature of the typical film growth mode by nucleation and grain coalescence, there is a high chance that discontinuities, such as small gaps, voids, and holes, are introduced into the borders of coalescing grains. A defect in the film that forms at these borders, such as a pinhole, allows a contaminate, such as oxygen or moisture, to reach the underlying doped region 102, leading to decreased lifetime and increased failure rate of the solar cell. Once a channel or void-like defect, such as a pinhole, is introduced during the initial stage of PECVD film growth, the pinhole will continue to the surface of the film as the film thickens.

Ammonia and silane gasses are commonly used for high rate deposition of PECVD silicon nitride films. The high deposition rate, however, generally results in film discontinuities leading to pinhole-like defects during the PECVD process. One method to decrease the formation of such defects is to decrease the deposition rate chemistry of the film by using ammonia, nitrogen, hydrogen, and silane. By carefully controlling the process conditions for ammonia, nitrogen, and silane precursors, near pinhole-free PECVD could be grown on a substrate at relatively lower deposition rates, such as 1,000 Å per minute. However, slower deposition rates mean longer production times for a given thickness of SiN. In general, an increase in gas flows of silane and ammonia increases the SiN deposition rate, but that also increases the likelihood of pinhole production.

However, if multiple layers of SiₓN_{y} films are deposited, pinhole-like defects in any one layer are not likely to align with those in another layer, and thus high deposition rates which are known to inherently result in such defects may still be used to form the sub-layers making up the passivation/ARC layer 120. Thus, the likelihood of pinholes extending between the top surface, i.e. the outer surface of bulk sub-layer 122, and the bottom surface, i.e. the interface between interface sub-layer 121 and doped region 102, can be significantly reduced. As shown in FIG. 1D, the passivation/ARC layer 120 is substantially free of pinholes 130, 131 that entirely pass through both the interface and bulk sub-layers. The pinholes 130, 131 generally are misaligned and create a “tortuous path”, i.e. the pathway from the top surface to the bottom surface would be a tortuous path because the pin holes do not form a generally straight passage or direct pathway between the two surfaces. In other words, pinholes may still form in the various sub-layers 121, 122, but the combined layers may be substantially free of pinholes that entirely pass though both layers, i.e. from a top surface of the bulk sub-layer to a bottom surface of the interface sub-layer.

In another embodiment of the invention, a method for pinhole detection on a c-Si (crystalline silicon) solar cell is provided. Pinhole sizes depend on the film grain sizes which typically range from tens of nanometers (nm) to several hundreds of nm in diameter/width. However, detection of such pinholes is not easy or straightforward unless the pinholes are abundant.

A technique using electroplating techniques may be used to reveal pinhole-like defects in a passivation layer(s) on a solar cell substrate, for example, a PECVD SiN on c-Si solar substrate. The advantage of this technique is that it can be applied to finished solar cells. A solar cell with passivation layers, such as PECVD SiN, is immersed in an electrolyte with an appropriate insulation of the rear-side of the solar cell while current is supplied through the metal-covered (e.g. Al) rear-side of the solar cells. Power is applied to the silicon, and if electrolyte comes into contact with the silicon, it forms a circuit, triggering plating of the pinhole.

Using this methodology, where the pinhole extends from the outer surface of the passivation/ARC layer 120 to the doped silicon region 102, metal from the plating solution, for example copper where the electrolyte includes CuSO₄, will plate onto the pinholes and start to grow over the pinhole, eventually plating outwards once it completely fills the pinholes. Metal, such as copper, however, will not plate in pinholes which do not extend entirely through the passivation/ARC layer 120, because where a pinhole extends to the doped layer 102, a circuit will be formed through the silicon and electrolyte, causing copper from the electrolyte to plate in the pinhole. The plated copper appears as bright circles on the face of the substrate, the sizes of which are much bigger than the pinhole openings, and vary in size from several microns to hundreds of microns, depending on the plating time. The glittering of the plated copper allows the pinholes to be detected under an optical microscope.

After formation of the silicon nitride-containing bulk sub-layer, the solar cell may be further processed to provide other protective layers as shown in FIGS. 1E and 1F illustrating two different embodiments of finished solar cell 100. FIG. 1E depicts a solar cell 100 having a multilayer passivation anti-reflection coating 120 on which a bonding material layer 124 and a glass substrate 126 is placed. The bonding material layer 124 encapsulates the solar cell substrate and any features formed thereon to form a protective layer with the glass substrate 126.

In another embodiment, to form a protective layer over the passivation layer, a third process gas mixture could be flown into the process volume to deposit a silicon, oxygen, nitrogen-containing layer, such as silicon-oxy-nitride (SiON), on the bulk sub-layer 122 as indicated in processes 207-208 and shown in FIG. 1F. This embodiment is typically made for lab studies and general research and testing. The silicon-oxynitride layer may have an n value of 1.9-1.8. The third process gas mixture may contain at least one of silane, octamethylcyclotetrasiloxane (OMCTS), tetraethyl orthosilicate (TEOS), O₂, O₃, N₂O, NO₂, NH₃, H₂, and N₂. This may be done in embodiments where no back glass cover or substrate will be used in the final structure of the solar cell.

The solar cell substrate may be annealed in a spike firing process at 850° C. for 1 second, as shown in 209. High temperature firing of the solar cell after silicon nitride deposition improves the quality of the bulk silicon nitride layer and drives the hydrogen into the substrate. The firing process may include various ramps to heat and cool down, which may depend on the type of pastes used in the solar cell. In another embodiment, the annealing could take place after depositing the silicon nitride-containing bulk sub-layer, as shown in 210. A bonding material, such as EVA or PVB is then placed on the bulk sub-layer after which a back glass substrate is disposed over the bonding material, and subsequently laminated to complete the solar cell manufacturing process, as shown in 211 and 212. Surface passivation, however, can be achieved regardless of whether or not a firing process is performed on the solar cell.

### Hardware Configuration

Plasma-enhanced chemical vapor deposition (PECVD) systems configured for processing large-area substrates can deposit SiN layers with superior film uniformity at high deposition rates. This is particularly true for parallel-plate, high frequency PECVD systems, wherein one or more substrates are positioned between two substantially parallel electrodes in a plasma chamber. The chamber's gas distribution plate generally acts as the first electrode and the chamber's substrate support as the second electrode. A precursor gas mixture is introduced into the chamber, energized into a plasma state by the application of radio frequency (RF) power to one of the electrodes, and flowed across a surface of the substrate to result in the deposition of a layer of desired material. The chamber geometry, with its gas showerhead directly above the plane of deposition, is optimal for creating the multiple graded layers at high throughput without adding substantial cost, size, or complexity to the system.

It is difficult to achieve both high n and low k properties of a silicon nitride passivation film with other types of processing chambers because it is hard to form high plasma power density layers in those processing chambers. For example, other processing chambers may use a carbon boat system with many substrates electronically connected together. Each substrate in the carbon boat system forms an anode and a cathode, which, it is believed, prevents a similar type of plasma as generated in the processing chambers described herein. However, with the PECVD tools described herein, it is believed that the capacitive coupling of a parallel plate type processing chamber enables the higher plasma power densities used to form passivation films with the desired optical and functional properties.

FIG. 3 is a schematic cross-sectional view of one embodiment of a plasma enhanced chemical vapor deposition (PECVD) chamber 300 in which one or more of the processes illustrated and discussed in conjunction with FIG. 2 may be performed. A similarly configured plasma enhanced chemical vapor deposition chamber is available from Applied Materials, Inc., located in Santa Clara, Calif. It is contemplated that other deposition chambers, including those from other manufacturers, may be utilized to practice the present invention.

It is believed that the plasma processing configuration provided in the processing chamber 300 has significant advantages over other configurations when used to perform one or more of the processes described in FIG. 2. In one embodiment, the PECVD chamber 300 is configured to process a plurality of substrates at one time. In one embodiment, the plasma enhanced chemical vapor deposition (PECVD) chamber 300 is adapted to simultaneously process a plurality of substrates 110 that are arranged in a planar array on substrate carrier 425 as shown in FIG. 4, as opposed to processing vertical stacks of substrates (e.g., batches of substrates stacked in cassettes such as is performed in vertical furnace systems). Processing the batches of substrates arranged in a planar array allows each of the substrates in the batch to be directly and simultaneously exposed to the generated plasma, radiant heat, and/or processing gases. Therefore, each substrate in the planar array is similarly processed in the process volume of a processing chamber, and thus does not rely on diffusion type processes and/or the serial transfer of energy to all substrates in a conventionally configured batch that is being processed, such as a stacked or back-to-back configured batch of substrates.

In one configuration, the PECVD chamber 300 is adapted to accept a substrate carrier 425 (FIGS. 3 and 4) that is configured to hold a batch of substrates during the transferring and processing of the substrates. In one embodiment, the substrate carrier 425 has a surface area of about 10,000 cm² or more, such as about 40,000 cm² or more, or about 55,000 cm² or more, that is configured to support a planar array of a plurality of substrates 110 disposed thereon during processing. In one embodiment, the substrate carrier 425 holds between about 4 and about 49 solar cell substrates that are 156 mm×156 mm×0.3 mm in size in a face-up or face-down configuration. In one configuration, a batch of solar cell substrates is transferred in a vacuum or inert environment (e.g., transfer chamber 420 in FIG. 4) on the substrate carrier 425 between a plurality of processing chambers to reduce the chance of contamination and improve throughput.

Referring again to FIG. 3, chamber 300 generally includes walls 302, a bottom 304, a showerhead 310, and a substrate support 330 which define a process volume 306. The process volume 306 is accessed through a valve 308 so that the substrates disposed on the substrate carrier 425, may be transferred in and out of the chamber 300. The substrate support 330 includes a receiving surface 332 and stem 334 coupled to a lift system, such as lift pins 338, to raise and lower the substrate support 330. A shadow frame 333, maintained within chamber 300, may be optionally placed over periphery of the substrate carrier 425. Lift pins 338 are moveably disposed through the substrate support 330 to move the substrate carrier 425 to and from the receiving surface 332. The substrate support 330 may also include embedded heating and/or cooling elements 338 to maintain the substrate support 330 at a desired temperature. The substrate support 330 may also include grounding straps 331 to provide RF grounding at the periphery of the substrate support 330. In one embodiment, the substrate support 330 has an RF source (not shown) that is coupled to an electrode (not shown) that is embedded in the substrate support 330 so that an RF bias can be applied to the substrates 110 disposed over the substrate support 330.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is coupled to the backing plate 312 to provide gas through the backing plate 312 and through the passages 311 of showerhead 310 to the substrate receiving surface 332. A vacuum pump 309 is coupled to the chamber 300 to control the process volume 306 at a desired pressure. An RF power source 322 is coupled to the backing plate 312 and/or to the showerhead 310 to provide a RF power to the showerhead 310 so that an electric field is created between the showerhead and the substrate support, thereby generating a capacitively coupled plasma using the gases disposed between the showerhead 310 and the substrate support 330. Various RF frequencies may be used, such as a frequency between about 0.3 MHz and about 100 MHz. It is believed that the direct contact of the capacitively coupled plasma to the processing surface 110A (FIG. 3) of the substrates 110 has advantages over designs that do not directly expose all of the substrates to the plasma, due to the ability of the chamber 300 configuration to provide energetic and/or ionized species directly to all parts of the processing surface 110A during processing.

In one embodiment, the heating and/or cooling elements 339 may be set to provide a substrate support temperature during deposition of about 400° C. or less, such as between about 100° C. and about 400° C. The spacing during deposition between the top surface of a substrate disposed on a substrate carrier 425 disposed on the substrate receiving surface 332 and the showerhead 310 may be between 300 mil and about 1,100 mil. For example, the spacing during deposition of the silicon nitride-containing interface sub-layer 121 may be between about 800 mil and about 1,100 mil during deposition of the silicon nitride-containing bulk sub-layer 122.

In another embodiment, a system for forming a film on a solar cell is disclosed. The system includes a plasma processing chamber, such as chamber 300, for forming a passivation/ARC layer 120 on a solar cell substrate 110 within a process volume 306 of the processing chamber. A system controller, for example computer 440, is in communication with the plasma processing chamber and configured to control the processing conditions and recipes for forming the interface sub-layer 121 and bulk sub-layer 122 of the passivation/ARC layer 120. The computer 440 may initiate the process conditions for forming the interface sub-layer 121 by controlling the flow rates and compositions of the gases comprising the first process gas mixture and the power density of the plasma generated from the first process gas mixture. After a certain deposition time or other event, the computer 440 can execute the transition from the first process gas mixture to the second process gas mixture for forming the bulk sub-layer 122, using any of the previously discussed transition types, such as a “break” transition. The computer 440 thus controls the process conditions in the processing chamber for forming each sub-layer so that the interface sub-layer and bulk sub-layer have tailored optical and passivating properties as previously discussed.

FIG. 4 is a top schematic view of one embodiment of a process system 400 having a plurality of processing chambers 431-437, such as PECVD chamber 300 of FIG. 3 or other suitable chambers capable of performing the processes described in conjunction with FIG. 2. The process system 400 includes a transfer chamber 420 coupled to a load lock chamber 410 and the process chambers 431-437. The load lock chamber 410 allows substrates to be transferred between the ambient environment outside the system and vacuum environment within the transfer chamber 420 and processing chambers 431-437. The load lock chamber 410 includes one or more evacuatable regions that are configured to hold one or more substrate carriers 425 that are configured to support a plurality of substrates 110. The evacuatable regions are pumped down during the input of the substrates into the system 400 and are vented during the output of the substrates from the system 400. The transfer chamber 420 has at least one vacuum robot 422 disposed therein that is adapted to transfer the substrate carriers 425 and substrates between the load lock chamber 410 and the processing chambers 431-437. Seven process chambers are shown in FIG. 4; however, the system 400 may have any suitable number of process chambers.

In one embodiment of system 400, a first processing chamber 431 is configured to perform process 201, a second processing chamber 432 is configured to perform processes 202-206, a third processing chamber 433 is configured to perform processes 207-208, and a fourth processing chamber 434 is configured to perform processes 209 or 210 on the substrates. Other embodiments may use various combinations of the processing chambers 431-437 of system 400 to perform processes 201-210. In yet another embodiment of system 400, at least one of the processing chambers 431-437 is configured to perform most of the processes, such as 201-210, on the substrates.

Using embodiments described herein, the silicon nitrogen-containing passivation/ARC layer 120 may be deposited at substantially faster rates than prior art processes while generally providing various passivation advantages without affecting the negatively quality of solar cell passivation layer. For example, the interface sub-layer contains some hydrogen and silicon radicals that can react with the dangling bonds of the silicon substrate to passivate the silicon substrate. The type of plasma chemistry formed for the deposition of the interface sub-layer has more hydrogen and silicon radicals than the plasma chemistry of the bulk sub-layer.

It is believed that when using other types of CVD chambers to perform plasma deposition, such as remote plasma deposition chambers, the components for making a silicon nitride layer are flown into the chamber at the right mixture in order to yield the right stoichiometric ratios, but does not permit much control over the film once it is deposited on the substrate. However, in a direct plasma process system, such as PECVD, the increased power breaks the weaker bonds, such as Si:Si bonds, to form stronger bonds while the film is being deposited on the substrate.

In deposition tools having a horizontal showerhead, such as shown in FIG. 3, the showerhead openings or passages 311 directly face the substrate, mixing gases with plasma going straight down on the substrate. Thus, the tool shown in FIG. 3 has the ability to rapidly change film layers on the fly, i.e. during processing, at high deposition rates by changing the gas mixtures entering the chamber. Thus, one advantage of embodiments of the invention is that single chambers may be used to deposit multiple silicon nitride passivation layers while providing the ability to vary gas flow into the chambers.

While the foregoing is directed to embodiments of the present invention, other and further embodiments of the invention may be devised without departing from the basic scope thereof, and the scope thereof is determined by the claims that follow.

What is claimed is:

1. A method of forming a passivation anti-reflection layer on a solar cell substrate, the method comprising:
flowing a first process gas mixture into a process volume within a processing chamber;
generating plasma in the processing chamber at a power density of greater than 0.65 W/cm²;
depositing a silicon nitride-containing interface sub-layer on a solar cell substrate in the process volume;
flowing a second process gas mixture into the process volume; and
depositing a silicon nitride-containing bulk sub-layer on the silicon nitride-containing interface sub-layer.

2. The method of claim 1, wherein the interface sub-layer has a refractive index (n) greater than that of the resulting bulk sub-layer and both the interface sub-layer and the bulk sub-layer have an extinction coefficient (k value) from 0 to 0.1.

3. The method of claim 2, wherein the interface sub-layer has a refractive index from 2.4 to 2.6 and the bulk sub-layer has a refractive index from 2.00 to 2.15.

4. The method of claim 1, wherein the first process gas mixture comprises nitrogen and silane.

5. The method of claim 4, wherein the nitrogen to silane ratio is 14:7.

6. The method of claim 4, wherein the nitrogen flow rate is about 77.30 sccm per liter of process volume and the silane flow rate is about 5.25 sccm per liter of process volume.

7. The method of claim 1, wherein the second process gas mixture comprises nitrogen, silane, and ammonia.

8. The method of claim 7, wherein the nitrogen to silane ratio is about 8.35 and the ammonia to silane ratio is about 0.90.

9. The method of claim 7, wherein the nitrogen flow rate is about 77.30 sccm per liter of process volume, the silane flow rate is about 9.20 sccm per liter of process volume, and the ammonia flow rate is about 8.40 sccm per liter of process volume.

10. The method of claim 1, wherein a spacing between the solar cell substrate and a showerhead in the process volume is about 800 mil during deposition of the silicon nitride-containing interface sub-layer and is about 1,000 mil during deposition of the silicon nitride-containing bulk sub-layer.

11. The method of claim 1, further comprising:
flowing a third process gas mixture into the process volume comprising at least one of silane, OMCTS, TEOS, O₂, O₃, N₂O, NO₂, NH₃, H₂, and N₂;
depositing a silicon, oxygen, nitrogen-containing layer on the bulk sub-layer; and
annealing the solar cell substrate at 850° C. for 1 second.

12. The method of claim 1, further comprising:
annealing the solar cell substrate at 850° C. for 1 second;
depositing a bonding material on the bulk sub-layer; and
disposing a back glass substrate over the bonding material.

13. The method of claim 1, wherein the passivation anti-reflective layer is substantially free of pinholes that entirely pass through both the interface and the bulk sub-layers.

14. The method of claim 1, further comprising:
extinguishing the plasma prior to flowing the second process gas mixture into the process volume, and
reigniting the plasma after flowing the second process gas mixture into the process volume.

15. A passivation/ARC layer formed in a solar cell device, comprising:
a silicon nitrogen-containing interface sub-layer disposed over one or more p-type doped regions formed in a surface of a solar cell; and
a silicon nitrogen-containing bulk sub-layer disposed over the silicon nitrogen-containing sub-layer, wherein the interface sub-layer has a refractive index (n) greater than that of the bulk sub-layer and both the interface sub-layer and the bulk sub-layer have an extinction coefficient (k value) from 0 to 0.1.

16. The passivation/ARC layer of claim 15, wherein an amount of net positive charge in the passivation/ARC layer has a charge density of greater than 1×10¹² Coulombs/cm² at the surface of the solar cell substrate.

17. The passivation/ARC layer of claim 15, wherein the passivation/ARC layer is substantially free of pinholes that entirely pass through both the interface and the bulk sub-layers.

18. A method for detecting pin-holes formed in a passivation layer on a solar cell, the method comprising:
immersing a solar cell having a passivation layer formed thereon in an electrolyte;
applying current through the metal covered rear-side of the solar cell to plate any pinholes that extend from an outer surface of the passivation layer to a doped region of the solar cell; and
detecting any metal that plates in any of the pinholes.

19. A solar cell, comprising:
a substrate having a junction region; and
a passivation anti-reflection layer on a surface of the substrate, the passivation anti-reflection layer comprising:
a silicon nitride-containing interface sub-layer; and
a silicon nitride-containing bulk sub-layer directly on the interface sub-layer, wherein the interface sub-layer has a refractive index (n) greater than the bulk sub-layer and wherein the passivation layer is substantially free of pinholes that entirely pass through both the interface sub-layer and the bulk sub-layer.

20. A system for forming a film on a solar cell, the system comprising:
a plasma processing chamber for forming a passivation/ARC layer on a solar cell substrate within a processing volume of the processing chamber, the passivation/ARC layer comprising:
a silicon nitride-containing interface sub-layer formed on the solar cell substrate using plasma generated from a first process gas mixture at a power density of greater than 0.65 W/cm²; and
a silicon nitride-containing bulk sub-layer formed on the interface sub-layer using plasma generated from a second process gas mixture at a power density of greater than 0.65 W/cm²; and
a system controller in communication with the plasma processing chamber, the system controller configured to control the plasma power density, the first process gas mixture flow rates, and the second process gas mixture flow rates so that the interface sub-layer has a refractive index (n) greater than that of the resulting bulk sub-layer and both the interface sub-layer and the bulk sub-layer have an extinction coefficient (k value) from 0 to 0.1.
